(19) United States
(12) Patent Application Publication
(10) Pub. No.: US 2026/0367123 A1
(43) Pub. Date: Nov. 19, 2026

(54) METHOD FOR EVALUATING FREQUENCY RESPONSE CHARACTERISTICS OF LINEAR OPTICAL MODULE

(71) Applicant: EOPTOLINK TECHNOLOGY INC., LTD, Chengdu City (CN)

(72) Inventors: Xiaolei Huang, Chengdu City (CN); Shuang Zeng, Chengdu City (CN); Zhuang Shao, Chengdu City (CN)

(21) Appl. No.: 19/557,186

(22) Filed: Mar. 5, 2026

(30) Foreign Application Priority Data
May 19, 2025 (CN) 202510639049.X

(51) Int. Cl. G01R 23/16; G01R 13/02

(52) U.S. Cl. CPC G01R 23/16; G01R 13/02

(57) ABSTRACT

Disclosed is a method for evaluating frequency response characteristics of a linear optical module, including: pattern generator transmitting signal to plug-in module, electrical oscilloscope capturing an electrical signal waveform output by plug-in module, and converting it to frequency domain to obtain frequency response characteristics from pattern generator to driver chip of linear optical module; pattern generator transmitting signal to linear optical module, optical oscilloscope capturing optical signal waveform output by linear optical module, and converting captured waveform to frequency domain to obtain frequency response characteristics from pattern generator to transmitter of linear optical module; and performing matrix element-wise division on frequency response characteristics from pattern generator to driver chip of linear optical module and frequency response characteristics from pattern generator to transmitter of linear optical module, to obtain frequency response characteristics of transmitter of linear optical module.

### CROSS-REFERENCE TO RELATED APPLICATION

The present disclosure claims the priority to the Chinese Patent Application No. 202510639049X, filed with the Chinese Patent Office on May 19, 2025, and entitled “METHOD FOR EVALUATING FREQUENCY RESPONSE CHARACTERISTICS OF LINEAR OPTICAL MODULE”, the contents of which are incorporated herein by reference in entirety.

### TECHNICAL FIELD

The present disclosure relates to the technical field of optical module performance testing, in particular to a method for evaluating frequency response characteristics of a linear optical module.

### BACKGROUND ART

With the rapid development of digital communication and AI technology, the demand for optical modules has increased sharply, among which linear optical modules are popular due to their low power consumption and low latency. While manufacturers mass-produce linear optical modules, it is very important to evaluate the performance of linear optical modules on the production line to ensure product quality. For linear optical modules, evaluating the frequency response characteristics of their transmitters is particularly important.

In the prior art, evaluating the frequency response characteristics of the transmitters of linear optical modules (such as linear-drive pluggable optics (LPO), co-packaged optics (CPO), etc.) based on vector network analyzers (VNA) and Lightwave component analyzers (LCA) is a common method. As shown in FIG. 1, the transmitter of the VNA outputs sine wave signals of different frequencies to a module compliance board (MCB, a type of test fixture), and then to the electrical receiver of the linear optical module (i.e., the device under test (DUT)). After the sine wave signals pass through the MCB and the linear optical module, they are output to the LCA. After photoelectric conversion by the LCA, the sine wave signal is finally returned to the VNA. The VNA compares the difference between the transmitted and received sine wave signals, and after removing the influence of the MCB, the frequency response characteristics of the transmitter of the linear optical module can be obtained. Evaluating the frequency response characteristics of the transmitter of a linear optical module based on VNA and LCA involves extremely high equipment costs. Moreover, after evaluating one channel in the linear optical module each time, it is necessary to replace the test fixture connection to test the next channel of the linear optical module, resulting in a long test time and extremely low efficiency for a single linear optical module. Therefore, there is a need for an optical module performance evaluation method suitable for large-scale mass production, especially a method for evaluating the frequency response characteristics of the transmitter of a linear optical module.

### SUMMARY

The objective of the present disclosure is to propose a method for evaluating the frequency response characteristics of the transmitter of a linear optical module suitable for production, which can effectively evaluate the frequency response characteristics of the transmitter of the linear optical module, save costs, improve efficiency, and provide manufacturability.

To achieve the above objective, embodiments of the present disclosure provide the following technical solutions.

A method for evaluating frequency response characteristics of a linear optical module includes the following steps:
step 1: connecting a plug-in module to a pattern generator, connecting an output end of the plug-in module to an electrical oscilloscope, the pattern generator transmitting a signal to the plug-in module, the electrical oscilloscope capturing an electrical signal waveform output by the plug-in module, and converting the electrical signal waveform to the frequency domain to obtain frequency response characteristics from the pattern generator to a driver chip of the linear optical module;
step 2: connecting the linear optical module to the pattern generator, connecting a transmitter of the linear optical module to an optical oscilloscope, the pattern generator transmitting a signal to the linear optical module, the optical oscilloscope capturing an optical signal waveform output by the linear optical module, and converting the captured waveform to the frequency domain to obtain frequency response characteristics from the pattern generator to the transmitter of the linear optical module; and
step 3: performing matrix element-wise division on the frequency response characteristics from the pattern generator to the driver chip of the linear optical module and the frequency response characteristics from the pattern generator to the transmitter of the linear optical module, to obtain frequency response characteristics of the transmitter of the linear optical module.

Compared with the prior art, the beneficial effects of the present disclosure are:

(1) The present disclosure is very suitable for mass production. The electrical oscilloscope is only used for evaluating the test equipment of BERT or BERT+MCB. The evaluated linear optical modules can be put into production without requiring a large number of electrical oscilloscopes; while optical oscilloscopes are commonly used equipment for optical module manufacturers and are available in large quantities. Therefore, the test equipment required by the present disclosure can fully achieve the test evaluation of large quantities of linear optical modules.

(2) The test efficiency of the present disclosure is high, allowing rapid evaluation of the frequency response characteristics of linear optical modules. After evaluation by the electrical oscilloscope, the modules can be tested in batches on the production line. For testing different channels of the optical transmitter, an optical switch can be used for switching tests without adjusting the test fixture, resulting in extremely fast test speed. Taking an 8-channel linear optical module as an example, the frequency response time for 8 channels is about 32 seconds, while the fixture adjustment and test time of the traditional VNA+LCA test method are longer, requiring about 240 seconds for the same test, and the costs of VNA and LCA are very high.

### BRIEF DESCRIPTION OF DRAWINGS

To illustrate the technical solutions of the embodiments of the present disclosure more clearly, the following drawings to be used in the embodiments will be briefly introduced. It is to be understood that the following drawings only show some embodiments of the present disclosure and therefore should not be considered as limiting the scope. For those of ordinary skill in the art, other related drawings can be obtained from these drawings without inventive effort.

FIG. 1 is a schematic diagram of a test device for frequency response characteristics of a transmitter of a linear optical module in the background art;

FIG. 2 is a schematic diagram of a test device for frequency response characteristics of a transmitter of a linear optical module in one embodiment of the present disclosure;

FIG. 3(a) is an equivalent schematic diagram of internal structure wiring of a linear optical module according to one embodiment of the present disclosure;

FIG. 3(b) is an equivalent schematic diagram of the path according to one embodiment of the present disclosure;

FIG. 4 is a schematic diagram of a test device for frequency response characteristics of a transmitter of a linear optical module in one embodiment of the present disclosure;

FIG. 5 is a comparison diagram of frequency response characteristics of the transmitter of the linear optical module between the present solution (dashed line) and the background art solution (solid line) when Gain=21 dB and peaking=0 dB for the linear optical module in one embodiment of the present disclosure;

FIG. 6 is a comparison diagram of frequency response characteristics of the transmitter of the linear optical module between the present solution (dashed line) and the background art solution (solid line) when Gain=21 dB and peaking=3 dB for the linear optical module in one embodiment of the present disclosure;

FIG. 7 is a comparison diagram of frequency response characteristics of the transmitter of the linear optical module between the present solution (dashed line) and the background art solution (solid line) when Gain=21 dB and peaking=0 dB for the linear optical module in one embodiment of the present disclosure;

FIG. 8 is a comparison diagram of frequency response characteristics of the transmitter of the linear optical module between the present solution (dashed line) and the background art solution (solid line) when Gain=21 dB and peaking=3 dB for the linear optical module in one embodiment of the present disclosure;

FIG. 9 is a diagram of frequency response characteristic from the bit error rate tester to the starting point of the driver chip of the linear optical module in one embodiment of the present disclosure;

FIG. 10 is a diagram of frequency response characteristic from the bit error rate tester to the transmitter of the linear optical module in one embodiment of the present disclosure;

FIG. 11 is a diagram of frequency response characteristic of the transmitter of the linear optical module in one embodiment of the present disclosure;

FIG. 12 is a diagram of frequency response characteristic from the bit error rate tester to the starting point of the driver chip of the linear optical module in one embodiment of the present disclosure;

FIG. 13 is a diagram of frequency response characteristic from the bit error rate tester to the transmitter of the linear optical module in one embodiment of the present disclosure;

FIG. 14 is a diagram of frequency response characteristic of the transmitter of the linear optical module in one embodiment of the present disclosure;

FIG. 15 is a diagram of frequency response characteristic from the bit error rate tester to the starting point of the driver chip of the linear optical module in one embodiment of the present disclosure;

FIG. 16 is a diagram of frequency response characteristic from the bit error rate tester to the transmitter of the linear optical module in one embodiment of the present disclosure;

FIG. 17 is a diagram of frequency response characteristic of the transmitter of the linear optical module in one embodiment of the present disclosure;

FIG. 18 is a diagram of frequency response characteristic from the bit error rate tester to the starting point of the driver chip of the linear optical module in one embodiment of the present disclosure;

FIG. 19 is a diagram of frequency response characteristic from the bit error rate tester to the transmitter of the linear optical module in one embodiment of the present disclosure; and

FIG. 20 is a diagram of frequency response characteristic of the transmitter of the linear optical module in one embodiment of the present disclosure.

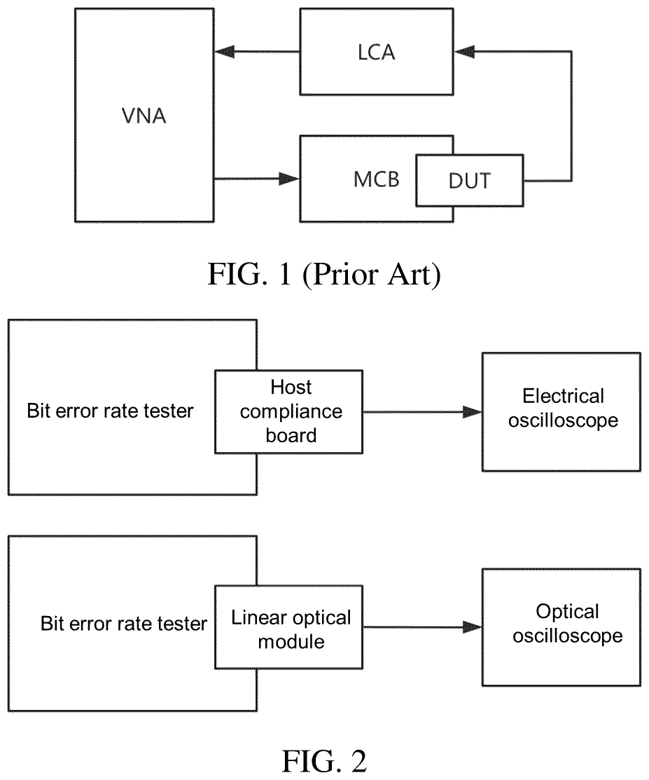

### DETAILED DESCRIPTION OF EMBODIMENTS

The technical solutions in the embodiments of the present disclosure will be clearly and completely described below with reference to the drawings in the embodiments of the present disclosure. It is to be understood that the described embodiments are only some, but not all, embodiments of the present disclosure. The components of the embodiments of the present disclosure generally described and illustrated in the drawings herein may be arranged and designed in various different configurations. Therefore, the following detailed description of the embodiments of the present disclosure provided in the drawings is not intended to limit the scope of the claimed disclosure, but merely represents selected embodiments thereof. Based on the embodiments of the present disclosure, all other embodiments obtained by those skilled in the art without inventive effort shall fall within the protection scope of the present disclosure.

It is to be noted that similar reference numerals and letters denote similar items in the following drawings. Thus, once an item is defined in one drawing, it requires no further definition or explanation in subsequent drawings. Meanwhile, in the description of the present disclosure, the terms “first”, “second”, etc. are used only for distinguishing description and cannot be understood as indicating or implying relative importance, or implying any such actual relationship or order between these entities or operations. In addition, terms such as “connected”, “coupled”, etc. may mean direct connection between elements or devices, or indirect connection via other elements or devices, or plug-in connection between elements or devices.

In one embodiment, the present disclosure is implemented through the following technical solution, providing a method for evaluating frequency response characteristics of a linear optical module, and for evaluating the frequency response characteristics of the transmitter of the linear optical module. As shown in FIG. 2, this method is implemented based on a set of test equipment. The test equipment includes: a pattern generator, a plug-in module, an electrical oscilloscope, and an optical oscilloscope. The pattern generator is configured to transmit signals to the plug-in module and the linear optical module to be evaluated. The plug-in module is connected to the electrical oscilloscope, and the electrical oscilloscope can capture the electrical signal waveform output by the plug-in module. The linear optical module is connected to the optical oscilloscope, and the optical oscilloscope can capture the optical signal waveform output by the linear optical module.

Specifically, the signal output by the pattern generator is a digital signal, so this solution preferably uses a bit error ratio tester (BERT) as the pattern generator. The signal pattern transmitted by the bit error rate tester to the plug-in module or the linear optical module is PRBSQ (Pseudo-Random Bit Sequence for Pulse Amplitude Modulation 4), for example, PRBS13Q (Pseudo-Random Bit Sequence 13 for Pulse Amplitude Modulation 4), or PRBS15Q (Pseudo-Random Bit Sequence 15 for Pulse Amplitude Modulation 4), etc. This embodiment does not limit the signal pattern transmitted by it, and it is only an example.

As a feasible implementation of this embodiment, the plug-in module is a host compliance board (HCB). The host compliance board is plugged into the bit error rate tester, and an output end of the host compliance board is connected to the electrical oscilloscope. The linear optical module is plugged into the bit error rate tester, an output end of the linear optical module is connected to the optical oscilloscope, and the linear optical module and the host compliance board are not plugged into the bit error rate tester simultaneously.

Based on this test equipment, the present disclosure proposes a method for evaluating frequency response characteristics of a linear optical module, including the following step 1 and step 2.

Step 1: connecting a plug-in module to a pattern generator, connecting an output end of the plug-in module to an electrical oscilloscope, the pattern generator transmitting a signal to the plug-in module, the electrical oscilloscope capturing an electrical signal waveform output by the plug-in module, and converting the electrical signal waveform to the frequency domain to obtain frequency response characteristics from the pattern generator to a driver chip of the linear optical module.

Specifically, the bit error ratio tester (BERT) in this embodiment has a module insertion port, so the plug-in module can be directly inserted into the bit error ratio tester using a host compliance board (HCB). The host compliance board is connected to the electrical oscilloscope via a radio frequency cable, and the electrical oscilloscope is a sampling oscilloscope or a real-time oscilloscope.

After completing the connection of the test equipment, the bit error rate tester outputs a signal to the host compliance board. The signal pattern is PRBS, preferably PRBS13Q, i.e., a pseudo-random sequence. The PRBS signal has rich frequency components, making it easier to achieve frequency sweeping compared to the single-frequency sine wave of a VNA. In this embodiment, the frequency signal output by the bit error rate tester can also be a signal of other patterns, provided that it can be captured by the electrical oscilloscope. When capturing the electrical signal waveform, the electrical oscilloscope needs to capture at least one complete PRBS pattern output by the bit error rate tester to avoid frequency truncation.

The host compliance board complies with TP1a (Test Point_1a) defined by the IEEE (Institute of Electrical and Electronics Engineers) protocol. The electrical oscilloscope captures the electrical signal output by the host compliance board and displays the waveform of the electrical signal. The bandwidth of the electrical oscilloscope needs to be greater than the Nyquist frequency of the signal under test (to avoid filtering out the fundamental frequency signal). In this embodiment, the bandwidth of the electrical oscilloscope is set to 39.8 GHZ, and the filter of the electrical oscilloscope uses a fourth-order Bessel filter. After the electrical oscilloscope captures the electrical signal output by the host compliance board, it uses the function of the forward feedback equalizer (FFE) of the electrical oscilloscope to optimize the electrical signal. Specifically, the forward feedback equalizer optimizes the electrical signal through the Minimum Mean Squared Error (MMSE) algorithm to obtain FFE coefficients. Then, a Fast Fourier Transform (FFT) is performed on the optimized FFE coefficients to convert the electrical signal from the time domain to the frequency domain, and then the logarithm is taken after dividing 1 by the frequency domain amplitude, thereby obtaining the frequency response characteristics from the bit error rate tester to the driver chip of the linear optical module.

The electrical signal captured by the electrical oscilloscope is equivalent to the signal from the bit error rate tester to the driver chip of the linear optical module. Therefore, through the electrical signal output by the host compliance board captured by the electrical oscilloscope, the frequency response characteristics from the bit error rate tester to the driver chip of the linear optical module can be obtained.

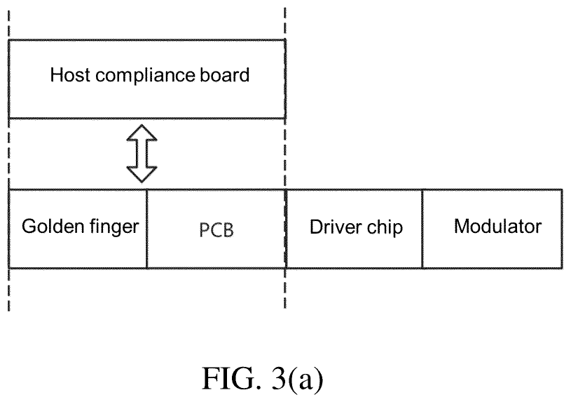

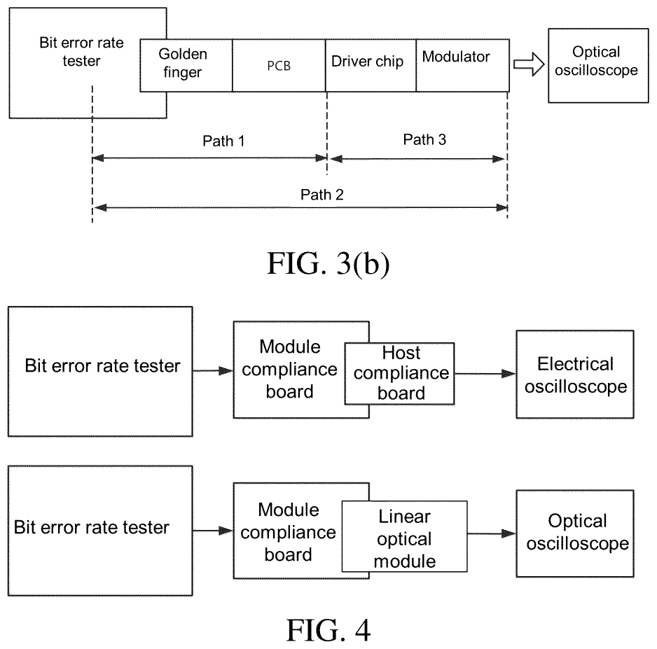

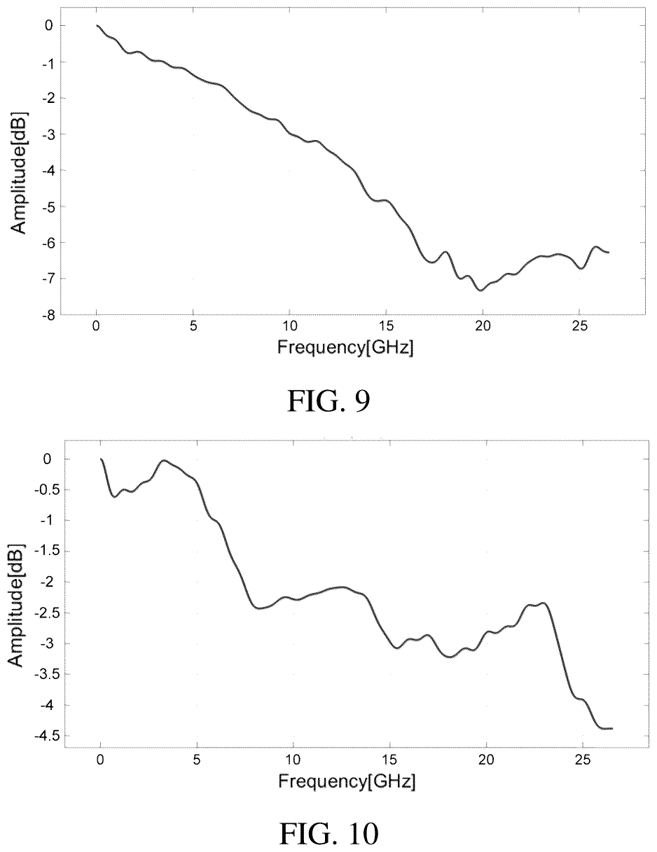

Specifically, as shown in FIG. 3(a), the structure of the linear optical module includes, sequentially from input to output: a gold finger (i.e., the slot of the electrical receiver of the linear optical module, equivalent to the electrical receiver), a section of PCB trace, a driver chip (i.e., Driver), a modulator, and a transmitter (the end point of the modulator is the transmitter of the linear optical module). After inserting the host compliance board into the bit error rate tester, the host compliance board is equivalent to the gold finger plus a section of PCB trace in the linear optical module, as shown in FIG. 3(a). Therefore, the electrical signal captured by the electrical oscilloscope is equivalent to the signal from the bit error rate tester to the driver chip of the linear optical module. In other words, it is the signal from the bit error rate tester to the gold finger and the signal from the gold finger through a section of PCB trace to the starting point of the driver chip. Therefore, the frequency response characteristics from the bit error rate tester to the driver chip of the linear optical module (or referred to as the frequency response characteristics from the bit error rate tester to the starting point of the driver chip of the linear optical module) can be obtained through the electrical signal captured by the electrical oscilloscope, which is equivalent to the frequency response characteristics of Path 1 in FIG. 3(b). FIG. 9 shows the diagram of frequency response characteristic from the bit error rate tester to the starting point of the driver chip of the linear optical module.

It should be noted that after the electrical oscilloscope captures the electrical signal output by the host compliance board, it is necessary to remove the radio frequency cable between the host compliance board and the electrical oscilloscope through the Remove S2P function of the electrical oscilloscope to eliminate the influence of the radio frequency cable on the frequency response characteristics.

Step 2: connecting the linear optical module to the pattern generator, connecting a transmitter of the linear optical module to an optical oscilloscope, the pattern generator transmitting a signal to the linear optical module, the optical oscilloscope capturing an optical signal waveform output by the linear optical module, and converting the captured waveform to the frequency domain to obtain frequency response characteristics from the pattern generator to the transmitter of the linear optical module.

Since the bit error rate tester has a module insertion port, after obtaining the frequency response characteristics from the bit error rate tester to the driver chip of the linear optical module, the host compliance board is pulled out from the bit error rate tester, and then the linear optical module (i.e., the Device Under Test, DUT) is inserted into the bit error rate tester in the same manner as the host compliance board. Alternatively, the linear optical module is inserted into another identical bit error rate tester in the same manner as the host compliance board, allowing step 2 and step 1 to be performed simultaneously or in no particular order to improve test efficiency. The linear optical module is connected to the optical oscilloscope via an optical fiber. The optical oscilloscope is a sampling oscilloscope or a real-time oscilloscope, but it should be the same as the selection of the electrical oscilloscope. In this embodiment, both the electrical oscilloscope and the optical oscilloscope use sampling oscilloscopes; or, both the electrical oscilloscope and the optical oscilloscope use real-time oscilloscopes.

After connecting the test equipment, the bit error rate tester outputs a signal to the linear optical module. The selection of this signal should be consistent with the signal output by the bit error rate tester to the host compliance board. In this embodiment, the PRBS pattern is used, preferably PRBS13Q. The optical signal output from the transmitter of the linear optical module is captured by the optical oscilloscope. When capturing the optical signal, the optical oscilloscope needs to capture at least one complete PRBS pattern output by the bit error rate tester to avoid frequency truncation. The bandwidth of the optical oscilloscope needs to be greater than the Nyquist frequency of the signal under test. In this embodiment, the bandwidth of the optical oscilloscope is set to 39.8 GHz, and the filter of the optical oscilloscope uses a fourth-order Bessel filter. It should be noted that the bandwidth of the optical oscilloscope should be consistent with that of the electrical oscilloscope to avoid test errors caused by bandwidth inconsistency.

After the optical oscilloscope captures the optical signal waveform emitted by the linear optical module, it optimizes the optical signal by using the function of the forward feedback equalizer (FFE) of the optical oscilloscope. Specifically, the forward feedback equalizer optimizes the optical signal through the minimum mean squared error (MMSE) algorithm to obtain FFE coefficients. Then, a Fast Fourier Transform (FFT) is performed on the optimized FFE coefficients to convert the optical signal from the time domain to the frequency domain, and then the logarithm is taken after dividing 1 by the frequency domain amplitude, thereby obtaining the frequency response characteristics from the bit error rate tester to the transmitter of the linear optical module.

Specifically, as shown in FIG. 3(a), the structure of the linear optical module includes, sequentially from input to output: a gold finger, a section of PCB trace, a driver chip, a modulator, and a transmitter. The optical signal captured by the optical oscilloscope is the signal from the bit error rate tester to the transmitter of the linear optical module, as can be seen in FIG. 3(b). Therefore, the frequency response characteristics from the bit error rate tester to the transmitter of the linear optical module, i.e., the frequency response characteristics of Path 2 in FIG. 3(b), can be obtained through the optical signal captured by the optical oscilloscope. FIG. 10 shows the diagram of frequency response characteristic from the bit error rate tester to the transmitter of the linear optical module.

step 3: performing matrix element-wise division on the frequency response characteristics from the pattern generator to the driver chip of the linear optical module and the frequency response characteristics from the pattern generator to the transmitter of the linear optical module, to obtain frequency response characteristics of the transmitter of the linear optical module.

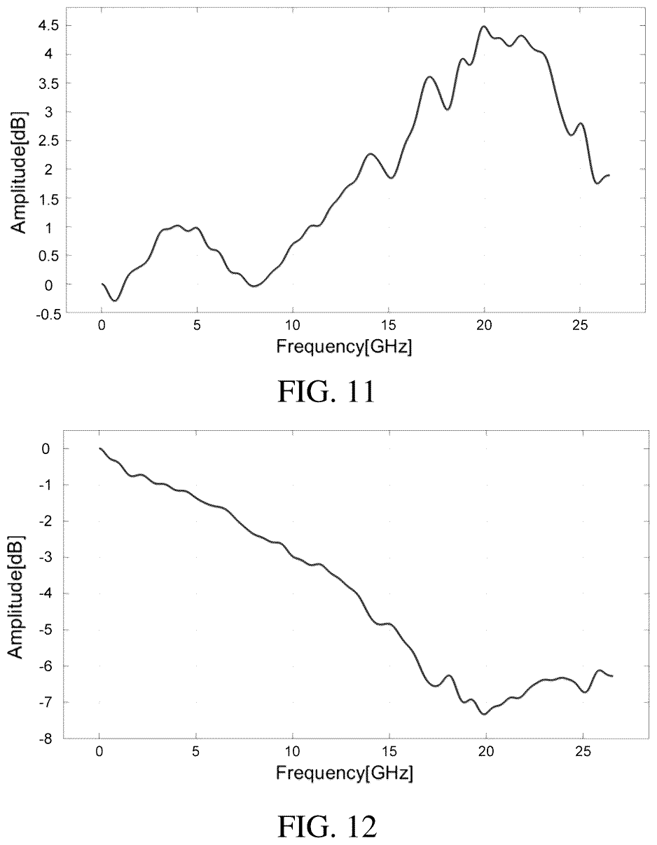

Based on the principle of matrix element-wise division in the frequency domain, which is the inverse application of the time-domain convolution theorem, matrix element-wise division is performed on the frequency response characteristics from the bit error rate tester to the driver chip of the linear optical module and the frequency response characteristics from the bit error rate tester to the transmitter of the linear optical module, as shown in FIG. 3(b). That is, the frequency response characteristics from the bit error rate tester to the starting point of the driver chip of the linear optical module (Path 1) is removed from the frequency response characteristics from the bit error rate tester to the transmitter of the linear optical module (Path 2), thereby obtaining the frequency response characteristics from the starting point of the driver chip of the linear optical module to the transmitter (Path 3), which is the frequency response characteristics of the transmitter of the linear optical module. As shown in FIG. 11, it is the diagram of frequency response characteristic of the transmitter of the linear optical module.

As another feasible implementation of this embodiment, as shown in FIG. 4, the plug-in module includes a module compliance board (MCB) and a host compliance board (HCB). The module compliance board is connected to the bit error rate tester via a radio frequency cable, the host compliance board is plugged into the module compliance board, and an output end of the host compliance board is connected to the electrical oscilloscope. The linear optical module is plugged into the module compliance board, an output end of the linear optical module is connected to the optical oscilloscope, and the linear optical module and the host compliance board are not plugged into the bit error rate tester simultaneously.

Based on this test equipment, the present disclosure proposes a method for evaluating frequency response characteristics of a linear optical module, including the following step 1 and step 2.

Step 1: connecting a plug-in module to a pattern generator, connecting an output end of the plug-in module to an electrical oscilloscope, the pattern generator transmitting a signal to the plug-in module, the electrical oscilloscope capturing an electrical signal waveform output by the plug-in module, and converting the electrical signal waveform to the frequency domain to obtain frequency response characteristics from the pattern generator to a driver chip of the linear optical module.

Specifically, the bit error ratio tester (BERT) does not have a module insertion port, so a module compliance board (MCB) is configured to achieve indirect connection between the bit error rate tester and the host compliance board. The bit error rate tester is connected to the module compliance board via a radio frequency cable, the host compliance board is plugged into the module compliance board, and an output end of the host compliance board is connected to the electrical oscilloscope via a radio frequency cable.

The electrical oscilloscope captures the electrical signal output by the host compliance board and displays the waveform of this electrical signal. After the electrical oscilloscope captures the electrical signal output by the host compliance board, it uses the function of the forward feedback equalizer (FFE) of the electrical oscilloscope to optimize the electrical signal. Specifically, the forward feedback equalizer optimizes the electrical signal through the Minimum Mean Squared Error (MMSE) algorithm to obtain FFE coefficients. Then, a Fast Fourier Transform (FFT) is performed on the optimized FFE coefficients to convert the electrical signal from the time domain to the frequency domain, and then the logarithm is taken after dividing 1 by the frequency domain amplitude, thereby obtaining the frequency response characteristics from the bit error rate tester to the driver chip of the linear optical module.

Step 2: connecting the linear optical module to the pattern generator, connecting a transmitter of the linear optical module to an optical oscilloscope, the pattern generator transmitting a signal to the linear optical module, the optical oscilloscope capturing an optical signal waveform output by the linear optical module, and converting the captured waveform to the frequency domain to obtain frequency response characteristics from the pattern generator to the transmitter of the linear optical module.

Since the bit error rate tester does not have a module insertion port, after connecting to the bit error rate tester via a radio frequency cable using the module compliance board, the host compliance board plugged into the module compliance board in step 1 is pulled out, and the linear optical module (i.e., the device under test, DUT) is inserted into the module compliance board in the same manner as the host compliance board. Alternatively, another identical module compliance board is connected to another identical bit error rate tester via a radio frequency cable, and the linear optical module is plugged into this module compliance board in the same manner as the host compliance board, so that step 1 and step 2 can be performed simultaneously or in no particular order to improve test efficiency. The linear optical module is connected to the optical oscilloscope via an optical fiber.

After the optical oscilloscope captures the optical signal emitted by the linear optical module, it optimizes the optical signal by using the function of the forward feedback equalizer (FFE) of the optical oscilloscope. Specifically, the forward feedback equalizer (FFE) optimizes the optical signal through the minimum mean squared error (MMSE) algorithm to obtain FFE coefficients. Then, a Fast Fourier Transform (FFT) is performed on the optimized FFE coefficients to convert the optical signal from the time domain to the frequency domain, and then the logarithm is taken after dividing 1 by the frequency domain amplitude, thereby obtaining the frequency response characteristics from the bit error rate tester to the transmitter of the linear optical module.

step 3: performing matrix element-wise division on the frequency response characteristics from the pattern generator to the driver chip of the linear optical module and the frequency response characteristics from the pattern generator to the transmitter of the linear optical module, to obtain frequency response characteristics of the transmitter of the linear optical module.

In this embodiment, the difference between the above implementations lies in whether the bit error rate tester has a module insertion port. If the bit error rate tester has a module insertion port, the host compliance board may be directly inserted into the bit error rate tester through the first implementation. Similarly, the linear optical module may also be directly inserted into the bit error rate tester. If the bit error rate tester does not have a module insertion port, then after connecting to the bit error rate tester via the module compliance board through the second implementation, the host compliance board or the linear optical module is inserted into the module compliance board.

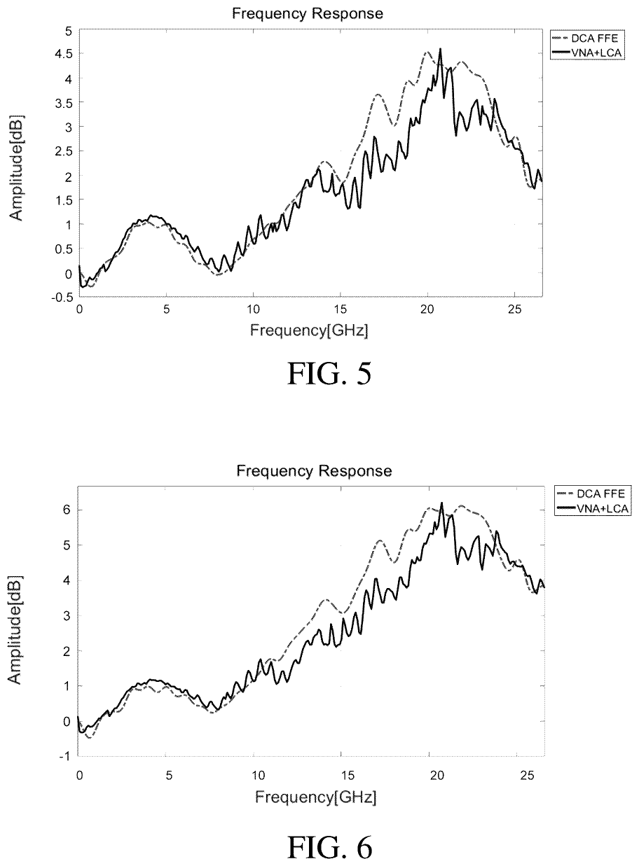

This solution can accurately evaluate the frequency response characteristics of the transmitter of the linear optical module. FIG. 5 shows the diagram of frequency response characteristic of the transmitter of the linear optical module for this solution (dashed line) and the background art solution (solid line) when Gain=21 dB and peaking=0 dB for the linear optical module, where the horizontal coordinate is the frequency and the vertical coordinate is the signal amplitude. FIG. 6 is a diagram of frequency response characteristic of the transmitter of the linear optical module for this solution (dashed line) and the background art solution (solid line) when Gain=21 dB and Peaking=3 dB for the linear optical module. It can be seen that the frequency response difference between this solution and the background art solution is small, but this solution saves costs, improves efficiency, and provides manufacturability compared to the background art. It should be noted that the frequency response characteristic comparison diagrams for the two implementations of the embodiment are both FIGS. 5 and 6, where Gain represents gain, peaking represents peak compensation, and dB represents decibel.

It should also be noted that there is no strict sequential order between step 1 and step 2 in this solution. Step 1 can be executed first and then step 2, or step 2 can be executed first and then step 1, or step 1 and step 2 can be executed simultaneously. In this solution, even if several linear optical modules are to be evaluated, it is only necessary to execute step 1 once to obtain the frequency response characteristics from the pattern generator to the driver chip of the linear optical module. For example, if the frequency response characteristics of the transmitters of 100 linear optical modules in this batch are to be evaluated, and each linear optical module has 8 optical channels, it can be achieved in at least the following three ways:

1. Executing step 1 once to obtain the frequency response characteristics from the pattern generator to the driver chip of the linear optical module; pulling out the host compliance board on the pattern generator used in step 1, inserting the first linear optical module into the pattern generator in the same way, and completing the test of all channels of this linear optical module in about 32 seconds; then directly replacing with the second linear optical module and inserting it into the pattern generator in the same way until all 100 linear optical modules are tested.

2. Executing step 1 once to obtain the frequency response characteristics from the pattern generator to the driver chip of the linear optical module; in step 2, inserting the linear optical module into another pattern generator with the same structure (the patterns transmitted by the two pattern generators are identical, the test of all channels of this linear optical module can be completed in about 32 seconds, and step 2 can be performed simultaneously with step 1 because two pattern generators with the same structure are used respectively); then pulling out the first linear optical module, directly replacing it with the second linear optical module and inserting it into the pattern generator in the same way until all 100 linear optical modules are tested.

3. Executing step 1 once to obtain the frequency response characteristics from the pattern generator to the driver chip of the linear optical module; in step 2, inserting the 100 linear optical modules into another 100 pattern generators with the same structure respectively. The patterns transmitted by these 100 pattern generators are identical. The test of all channels of the 100 linear optical modules can be completed in about 32 seconds, and step 2 can be performed simultaneously with step 1 because 100 pattern generators with the same structure are used respectively.

It can be seen that compared to the VNA+LCA solution used in the background art, since the cost of VNA and LCA is very high, this solution can not only significantly reduce costs, but also shorten evaluation time and improves efficiency because manufacturers producing linear optical modules have a large number of pattern generators and optical oscilloscopes.

In another embodiment, based on the test equipment of the two feasible implementations in the above embodiment, as shown in FIG. 2, the present disclosure proposes a method for evaluating frequency response characteristics of a linear optical module, including the following steps 1 to 3.

Step 1: connecting the plug-in module to the pattern generator, connecting an output end of the plug-in module to the electrical oscilloscope, the pattern generator transmitting a signal to the plug-in module, the electrical oscilloscope capturing an electrical signal waveform output by the plug-in module, and converting the captured waveform to the frequency domain to obtain frequency response characteristics from the pattern generator to a receiver of the linear optical module.

This embodiment differs from the above embodiment in that, since the electrical oscilloscope needs to remove the radio frequency cable between the host compliance board and the electrical oscilloscope through the Remove S2P function of the electrical oscilloscope after capturing the electrical signal output by the host compliance board, the host compliance board is equivalent to a section of PCB trace between the gold finger and the starting point of the driver chip in the linear optical module. If the accurate S-parameter model of the host compliance board is further known (the S-parameter model refers to an S-parameter file that can reflect frequency response characteristics, and this S-parameter file usually contains amplitude and phase corresponding to different frequencies), the S-parameter model can be removed through the Remove S2P function of the electrical oscilloscope. Referring to FIG. 3(a), the electrical signal obtained after removal is equivalent to the signal from the bit error rate tester to the gold finger, i.e., the signal from the bit error rate tester to the receiver of the linear optical module, thereby obtaining the frequency response characteristics from the bit error rate tester to the receiver of the linear optical module.

Step 2: connecting the linear optical module to the pattern generator, connecting a transmitter of the linear optical module to an optical oscilloscope, the pattern generator transmitting a signal to the linear optical module, the optical oscilloscope capturing an optical signal waveform output by the linear optical module, and converting the captured waveform to the frequency domain to obtain frequency response characteristics from the pattern generator to the transmitter of the linear optical module.

Step 3: performing matrix element-wise division on the frequency response characteristics from the pattern generator to the receiver of the linear optical module and the frequency response characteristics from the pattern generator to the transmitter of the linear optical module, to obtain frequency response characteristics of the linear optical module.

Based on the principle of matrix element-wise division in the frequency domain, which is the inverse application of the time-domain convolution theorem, matrix element-wise division is performed on the frequency response characteristics from the bit error rate tester to the receiver of the linear optical module and the frequency response characteristics from the bit error rate tester to the transmitter of the linear optical module. In other words, the frequency response characteristics from the bit error rate tester to the receiver of the linear optical module are removed from the frequency response characteristics from the bit error rate tester to the transmitter of the linear optical module, thereby obtaining the frequency response characteristics from the receiver to the transmitter of the linear optical module, which is the frequency response characteristics of the entire linear optical module.

Other parts of this embodiment are the same as Embodiment 1, and thus are not repeated here.

In a further embodiment, the difference between this embodiment and the embodiments above is that the electrical oscilloscope and the optical oscilloscope do not have the function of a forward feedback equalizer (FFE), then the electrical signal waveform and the optical signal waveform need to be saved and exported.

After exporting the electrical signal waveform or the optical signal waveform, channel estimation is first performed based on the Least Squares (LS) solution to obtain the channel matrix H, signal power

$${σ}_{a}^{2} ,$$

and noise power

$${σ}_{n}^{2} .$$

The specific steps are as follows:

transmitting a known PRBS signal at a transmitter of a channel, and capturing a channel output waveform at a receiver of the channel using an electrical oscilloscope/optical oscilloscope, and determining the following relationship based on a least squares solution:

H₁=(X^{H}X)⁻¹X^{H}Y

where H₁ is a channel impulse response matrix with a dimension of N₁×1, N₁ being a pulse length for channel estimation; X is a PRBS signal matrix input to the channel with a dimension of N₂×N₁ and is a cyclic matrix, N₂ being a PRBS signal length; X^{H} is the Hermitian matrix of X; and Y is a channel output signal matrix captured by the optical oscilloscope/electrical oscilloscope with a dimension of N₂×1.

The convolution matrix of the channel impulse response matrix H₁ is the channel matrix Ĥ, and the dimension of the channel matrix Ĥ is (N₁+N−1)×N, where N is an FFE coefficient length.

Based on the channel matrix Ĥ, the FFE coefficients are calculated according to the minimum mean squared error (MMSE) algorithm:

$$G = {{\hat{H}}^{H} ( \hat{H} {\hat{H}}^{H} + \frac{{σ}_{n}^{2}}{{σ}_{a}^{2}} I )}^{- 1}$$

where G is the FFE coefficient with a dimension of N×(N₁+N−1); HH is the Hermitian matrix of Ĥ; the square of the maximum value of the channel impulse response matrix H₁ is the signal power

$${σ}_{a}^{2} ;$$

the variance of H₁X−Y is the noise power

$${σ}_{n}^{2} ;$$

I is an identity matrix with a dimension of (N₁+N−1)×(N₁+N−1).

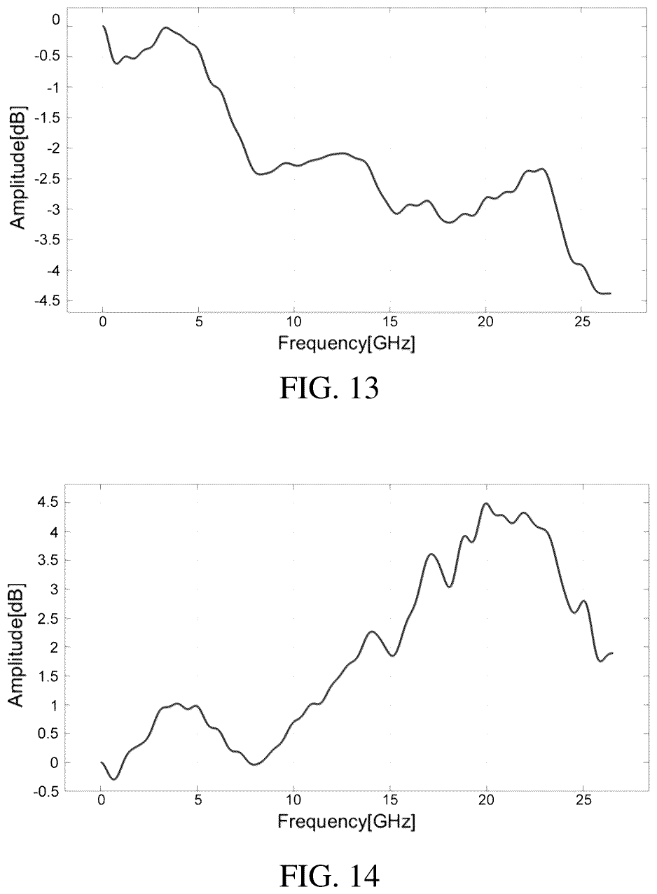

Based on the above embodiment, after exporting the electrical signal and the optical signal, a Fast Fourier Transform (FFT) is performed on the FFE coefficients optimized by an external algorithm to convert them from the time domain to the frequency domain, and then the logarithm is taken after dividing 1 by the frequency domain amplitude, thereby obtaining the frequency response characteristics from the bit error rate tester to the starting point of the driver chip of the linear optical module, as shown in FIG. 12. The frequency response characteristics from the bit error rate tester to the transmitter of the linear optical module can also be obtained, as shown in FIG. 13. Matrix element-wise division is performed on the frequency response characteristics from the bit error rate tester to the starting point of the driver chip of the linear optical module and the frequency response characteristics from the bit error rate tester to the transmitter of the linear optical module, thereby obtaining the frequency response characteristics of the transmitter of the linear optical module, as shown in FIG. 14.

Other parts of this embodiment are the same as the other embodiments described above and thus are not repeated here.

In yet another embodiment, in one solution, based on the test equipment proposed in Embodiment 1, this embodiment proposes a method for evaluating frequency response characteristics of a linear optical module, including the following steps 1 to 3.

Step 1: connecting a plug-in module to a pattern generator, connecting an output end of the plug-in module to an electrical oscilloscope, the pattern generator transmitting a signal to the plug-in module, the electrical oscilloscope capturing an electrical signal waveform output by the plug-in module, and converting the electrical signal waveform to the frequency domain to obtain frequency response characteristics from the pattern generator to a driver chip of the linear optical module.

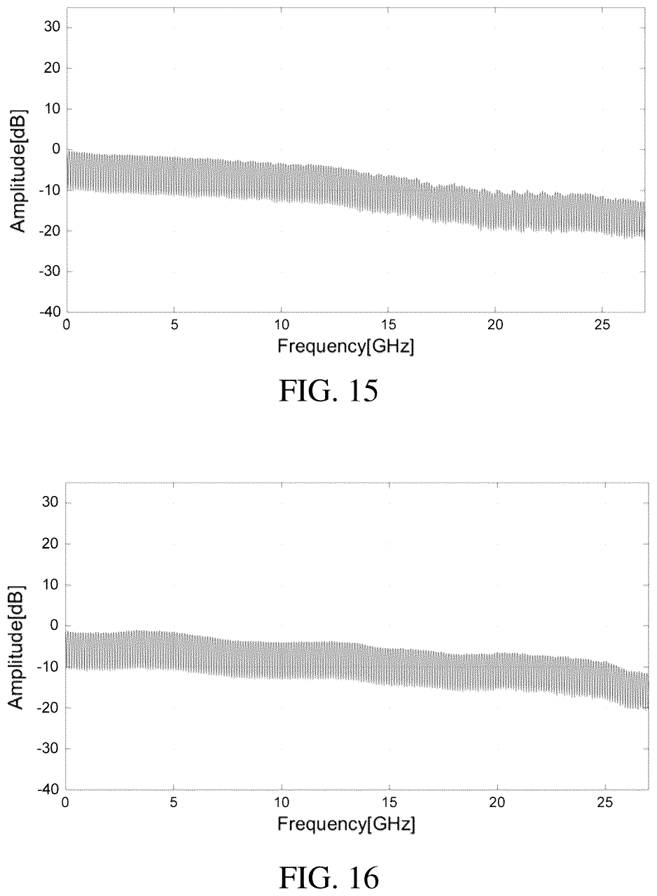

After the electrical oscilloscope captures the electrical signal output by the host compliance board, the electrical oscilloscope converts the electrical signal from the time domain to the frequency domain through a Fast Fourier Transform (FFT), thereby obtaining the frequency response characteristics from the bit error rate tester to the starting point of the driver chip of the linear optical module, as shown in FIG. 15.

Step 2: connecting the linear optical module to the pattern generator, connecting a transmitter of the linear optical module to an optical oscilloscope, the pattern generator transmitting a signal to the linear optical module, the optical oscilloscope capturing an optical signal waveform output by the linear optical module, and converting the captured waveform to the frequency domain to obtain frequency response characteristics from the pattern generator to the transmitter of the linear optical module.

After the optical oscilloscope captures the optical signal emitted by the linear optical module, the optical oscilloscope converts the optical signal from the time domain to the frequency domain through a Fast Fourier Transform (FFT), thereby obtaining the frequency response characteristics from the bit error rate tester to the transmitter of the linear optical module, as shown in FIG. 16.

Step 3: performing matrix element-wise division on the frequency response characteristics from the pattern generator to the driver chip of the linear optical module and the frequency response characteristics from the pattern generator to the transmitter of the linear optical module, to obtain frequency response characteristics of the transmitter of the linear optical module.

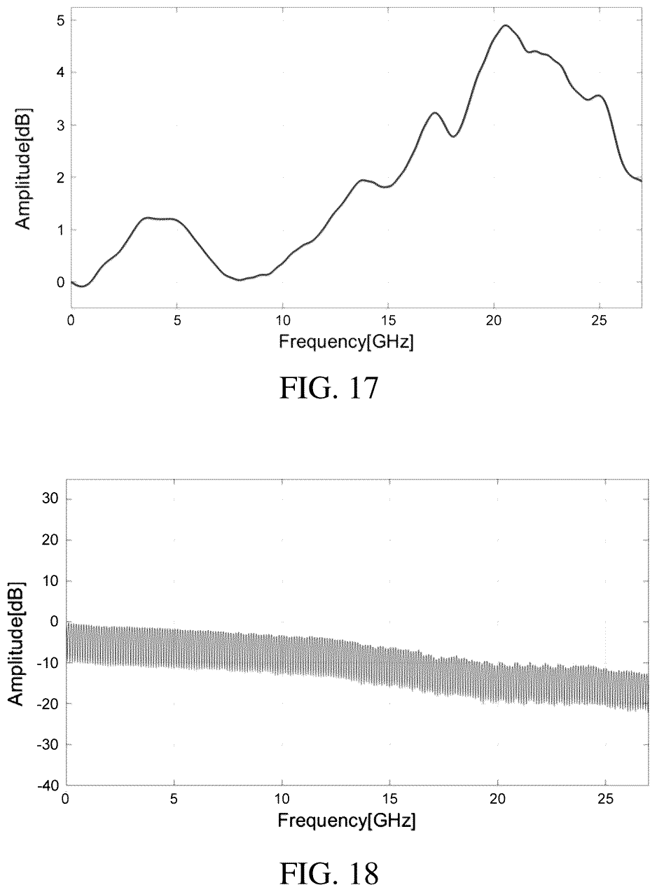

Based on the principle of matrix element-wise division in the frequency domain, which is the inverse application of the time-domain convolution theorem, matrix element-wise division is performed on the frequency response characteristics from the bit error rate tester to the starting point of the driver chip of the linear optical module and the frequency response characteristics from the bit error rate tester to the transmitter of the linear optical module, and then piecewise fourth-order polynomial fitting is configured to reduce the influence of spectral noise, thereby obtaining the frequency response characteristics of the transmitter of the linear optical module, as shown in FIG. 17.

The difference between this embodiment and the embodiments above is that in step 1 and step 2, no FFE optimization is performed on the captured electrical signal and optical signal; instead, a Fast Fourier Transform (FFT) is directly performed, and the operation of taking the logarithm after dividing 1 by the frequency domain amplitude is not performed on the FFT result. However, after performing matrix element-wise division in step 3, it is necessary to use piecewise fourth-order polynomial fitting to reduce the influence of spectral noise, thereby obtaining the frequency response characteristics of the transmitter of the linear optical module.

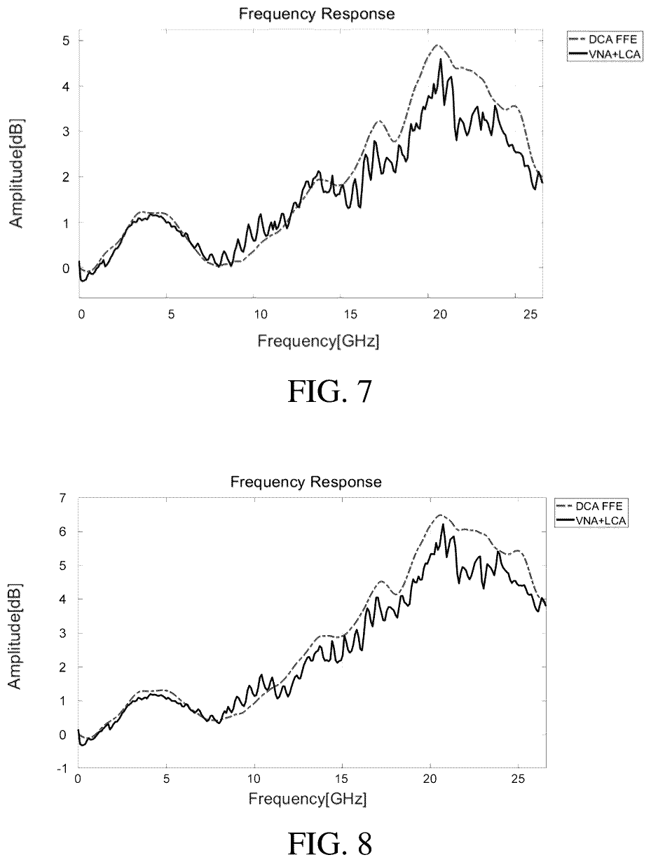

This embodiment can accurately evaluate the frequency response characteristics of the transmitter of the linear optical module. In the solution where the electrical oscilloscope and optical oscilloscope do not perform FFE optimization on the electrical signal and optical signal but directly perform FFT, FIG. 7 shows the diagram of frequency response characteristic of the transmitter of the linear optical module for this embodiment (dashed line) and the background art solution (solid line) when Gain=21 dB and peaking=0 dB for the linear optical module, where the horizontal coordinate is the frequency and the vertical coordinate is the signal amplitude. FIG. 8 is a diagram of frequency response characteristic of the transmitter of the linear optical module for this embodiment (dashed line) and the background art solution (solid line) when Gain=21 dB and Peaking=3 dB for the linear optical module. It can be seen that the frequency response difference between this solution and the background art solution is small, but this solution saves costs, improves efficiency, and provides manufacturability compared to the background art. It should be noted that the frequency response characteristic comparison diagrams for the two solutions in Embodiment 1 are both FIG. 7 and FIG. 8. where Gain represents gain, peaking represents peak compensation, and dB represents decibel.

Other parts of this embodiment are the same as Embodiment 1, and thus are not repeated here.

In another solution, this embodiment may also be implemented based on the above embodiments.

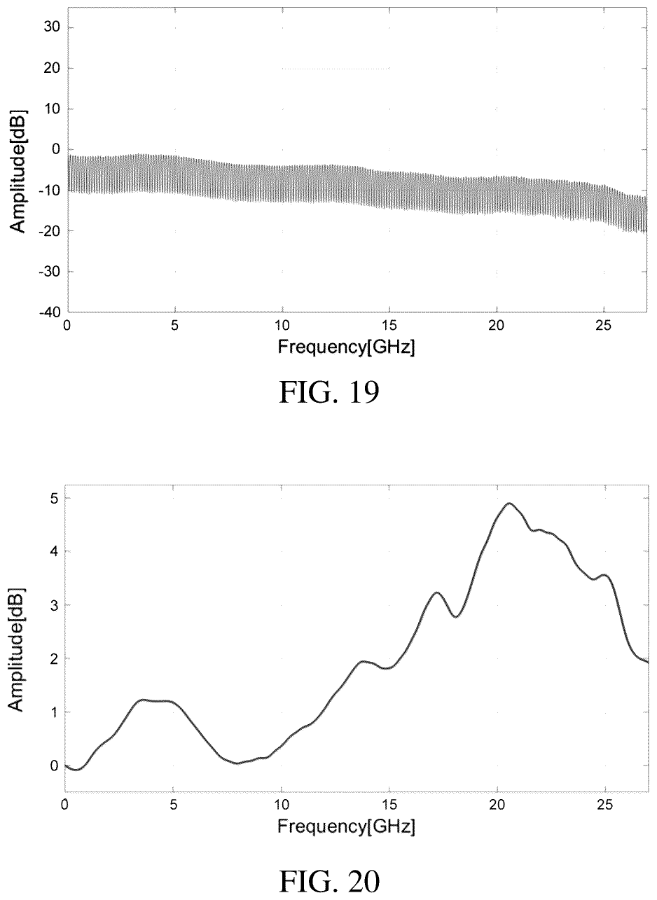

In yet another embodiment, in this embodiment, based on Embodiment 1, the electrical signal waveform captured by the electrical oscilloscope and the optical signal waveform captured by the optical oscilloscope are saved and exported. An external Fast Fourier Transform (FFT) algorithm is configured to convert the electrical signal and the optical signal from the time domain to the frequency domain, thereby obtaining the frequency response characteristics from the bit error rate tester to the starting point of the driver chip of the linear optical module as shown in FIG. 18, and obtaining the frequency response characteristics from the bit error rate tester to the transmitter of the linear optical module as shown in FIG. 19. Finally, after performing matrix element-wise division, piecewise fourth-order polynomial fitting is used to reduce the influence of spectral noise, thereby obtaining the frequency response characteristics of the transmitter of the linear optical module as shown in FIG. 20.

In this embodiment, in step 1 and step 2, the captured electrical signal and optical signal are saved and exported without FFE optimization, and an external Fast Fourier Transform (FFT) is directly performed, and the operation of taking the logarithm after dividing 1 by the frequency domain amplitude is not performed on the FFT result. However, after performing matrix element-wise division in step 3, it is necessary to use external piecewise fourth-order polynomial fitting to reduce the influence of spectral noise, thereby obtaining the frequency response characteristics of the transmitter of the linear optical module.

The above are only specific implementations of the present disclosure, and are not intended to limit the scope thereof. Any person skilled in the art could readily conceive of variations or substitutions within the technical scope disclosed herein. All such variations and substitutions shall fall within the scope of protection of the present disclosure. Therefore, the protection scope of the present disclosure shall be defined by the appended claims.

What is claimed is:

1. A method for evaluating frequency response characteristics of a linear optical module, comprising the following steps:
step 1, connecting a plug-in module to a pattern generator, connecting an output end of the plug-in module to an electrical oscilloscope, the pattern generator transmitting a signal to the plug-in module, the electrical oscilloscope capturing an electrical signal waveform output by the plug-in module, and converting the electrical signal waveform to the frequency domain to obtain frequency response characteristics from the pattern generator to a driver chip of the linear optical module;
step 2: connecting the linear optical module to the pattern generator, connecting a transmitter of the linear optical module to an optical oscilloscope, the pattern generator transmitting a signal to the linear optical module, the optical oscilloscope capturing an optical signal waveform output by the linear optical module, and converting the captured optical signal waveform to the frequency domain to obtain frequency response characteristics from the pattern generator to the transmitter of the linear optical module; and
step 3: performing matrix element-wise division on the frequency response characteristics from the pattern generator to the driver chip of the linear optical module and the frequency response characteristics from the pattern generator to the transmitter of the linear optical module, to obtain frequency response characteristics of the transmitter of the linear optical module.

2. The method for evaluating frequency response characteristics of a linear optical module according to claim 1, wherein the pattern generator is a bit error rate tester.

3. The method for evaluating frequency response characteristics of a linear optical module according to claim 2, wherein the signal pattern transmitted by the bit error rate tester to the plug-in module and the linear optical module is PRBS.

4. The method for evaluating frequency response characteristics of a linear optical module according to claim 3, wherein under a condition that the electrical oscilloscope captures the electrical signal waveform and the optical oscilloscope captures the optical signal waveform, at least one complete PRBS pattern output by the bit error rate tester needs to be captured.

5. The method for evaluating frequency response characteristics of a linear optical module according to claim 1, wherein the plug-in module is a host compliance board, and the method further comprises:
in step 1, plugging the host compliance board into the pattern generator, and connecting an output end of the host compliance board to the electrical oscilloscope via a radio frequency cable; and
in step 2, pulling out the host compliance board from the pattern generator, plugging the linear optical module into the pattern generator, and connecting the transmitter of the linear optical module to the optical oscilloscope via an optical fiber; or, in step 2, plugging the linear optical module into another identical pattern generator, and connecting the transmitter of the linear optical module to the optical oscilloscope via an optical fiber.

6. The method for evaluating frequency response characteristics of a linear optical module according to claim 1, wherein the plug-in module comprises a module compliance board and a host compliance board, and the method further comprises:
in step 1, connecting the module compliance board to the pattern generator via a radio frequency cable, plugging the host compliance board into the module compliance board, and connecting an output end of the host compliance board to the electrical oscilloscope via a radio frequency cable; and
in step 2, pulling out the host compliance board from the module compliance board, plugging the linear optical module into the module compliance board, and connecting the transmitter of the linear optical module to the optical oscilloscope via an optical fiber; or, in step 2, connecting another identical module compliance board to another identical pattern generator via a radio frequency cable, plugging the linear optical module into the module compliance board, and connecting the transmitter of the linear optical module to the optical oscilloscope via an optical fiber.

7. The method for evaluating frequency response characteristics of a linear optical module according to claim 1, wherein
in step 1, the step of the electrical oscilloscope capturing an electrical signal waveform output by the plug-in module, and converting the electrical signal waveform to the frequency domain to obtain frequency response characteristics from the pattern generator to a driver chip of the linear optical module specifically comprises:
optimizing, after the electrical oscilloscope captures the electrical signal waveform output by the host compliance board, the electrical signal using a forward feedback equalizer function of the electrical oscilloscope, the forward feedback equalizer optimizing the electrical signal through a minimum mean square error algorithm to obtain FFE coefficients; then performing a Fast Fourier Transform on the optimized FFE coefficients to convert the electrical signal from the time domain to the frequency domain, and then taking the logarithm after dividing 1 by the frequency domain amplitude, thereby obtaining the frequency response characteristics from the pattern generator to the driver chip of the linear optical module; and
in step 2, the step of the optical oscilloscope capturing an optical signal waveform output by the linear optical module, and converting the captured waveform to the frequency domain to obtain frequency response characteristics from the pattern generator to the transmitter of the linear optical module specifically comprises:
optimizing, after the optical oscilloscope captures the optical signal waveform emitted by the linear optical module, the optical signal using a forward feedback equalizer function of the optical oscilloscope, the forward feedback equalizer optimizing the optical signal through a minimum mean square error algorithm to obtain FFE coefficients; then performing a Fast Fourier Transform on the optimized FFE coefficients to convert the optical signal from the time domain to the frequency domain, and then taking the logarithm after dividing 1 by the frequency domain amplitude, thereby obtaining the frequency response characteristics from the pattern generator to the transmitter of the linear optical module.

8. The method for evaluating frequency response characteristics of a linear optical module according to claim 1, wherein in step 1 and step 2, after the electrical oscilloscope captures the electrical signal waveform output by the plug-in module and the optical oscilloscope captures the optical signal waveform output by the linear optical module, the electrical signal waveform and the optical signal waveform are saved and exported, FFE coefficients are calculated using an external algorithm, channel estimation is performed first based on a least squares solution to obtain a channel matrix Ĥ, signal power
$${σ}_{a}^{2} ,$$
and noise power
$${σ}_{n}^{2} ,$$
and the specific steps are as follows:
transmitting a known PRBS signal at a transmitter of a channel, capturing a channel output waveform at a receiver of the channel using an electrical oscilloscope/optical oscilloscope, and determining a following relationship based on a least squares solution:
H₁=(X^{H}X)⁻¹X^{H}Y
where H₁ is a channel impulse response matrix with a dimension of N₁×1, N₁ being a pulse length for channel estimation; X is a PRBS signal matrix input to the channel with a dimension of N₂×N₁ and is a cyclic matrix, N₂ being a PRBS signal length; X^{H} is a Hermitian matrix of X; and Y is a channel output signal matrix captured by the optical oscilloscope/electrical oscilloscope with a dimension of N₂×1;
a convolution matrix of the channel impulse response matrix H₁ is a channel matrix Ĥ with a dimension of (N₁+N−1)×N, where Nis an FFE coefficient length; and
based on the channel matrix Ĥ, calculating FFE coefficients according to the minimum mean square error algorithm:
$$G = {{\hat{H}}^{H} ( \hat{H} {\hat{H}}^{H} + \frac{{σ}_{n}^{2}}{{σ}_{a}^{2}} I )}^{- 1}$$
where G is an FFE coefficient with a dimension of N×(N₁+N−1); Ĥ^{H} is the Hermitian matrix of H; the square of the maximum value of the channel impulse response matrix H₁ is the signal power
$${σ}_{a}^{2} ;$$
the variance of H₁X−Y is the noise power
$${σ}_{n}^{2} ;$$
I is an identity matrix with a dimension of (N₁+N−1)×(N₁+N−1).

9. The method for evaluating frequency response characteristics of a linear optical module according to claim 1, wherein
in step 1, the step of the electrical oscilloscope capturing an electrical signal waveform output by the plug-in module, and converting the electrical signal waveform to the frequency domain to obtain frequency response characteristics from the pattern generator to a driver chip of the linear optical module specifically comprises:
capturing, by the electrical oscilloscope, the electrical signal waveform output by the host compliance board, and performing a Fast Fourier Transform to convert the electrical signal from the time domain to the frequency domain, to obtain the frequency response characteristics from the pattern generator to the driver chip of the linear optical module;
in step 2, the step of the optical oscilloscope capturing an optical signal waveform output by the linear optical module, and converting the captured waveform to the frequency domain to obtain frequency response characteristics from the pattern generator to the transmitter of the linear optical module specifically comprises:
capturing, by the optical oscilloscope, the optical signal waveform emitted by the linear optical module, and performing a Fast Fourier Transform to convert the optical signal from the time domain to the frequency domain, to obtain the frequency response characteristics from the pattern generator to the transmitter of the linear optical module; and
in step 3, after performing matrix element-wise division on the frequency response characteristics from the pattern generator to the driver chip of the linear optical module and the frequency response characteristics from the pattern generator to the transmitter of the linear optical module, the method further comprises:
using piecewise fourth-order polynomial fitting to reduce the influence of spectral noise, thereby obtaining the frequency response characteristics of the transmitter of the linear optical module.

10. The method for evaluating frequency response characteristics of a linear optical module according to claim 5, further comprising:
in step 1, after the electrical oscilloscope captures the electrical signal output by the host compliance board, removing the S-parameter model via a Remove S2P function of the electrical oscilloscope according to a known S-parameter model of the host compliance board, thereby obtaining frequency response characteristics from the pattern generator to a receiver of the linear optical module; and
in step 3, performing matrix element-wise division on the frequency response characteristics from the pattern generator to the receiver of the linear optical module and the frequency response characteristics from the pattern generator to the transmitter of the linear optical module, to obtain frequency response characteristics of the linear optical module.

11. The method for evaluating frequency response characteristics of a linear optical module according to claim 1, further comprising: in step 1, after the electrical oscilloscope captures the electrical signal waveform output by the plug-in module, removing the radio frequency cable between the host compliance board and the electrical oscilloscope via a Remove S2P function of the electrical oscilloscope.
